(19) United States
(12) Patent Application Publication
(10) Pub. No.: US 2026/0126502 A1
(43) Pub. Date: May 7, 2026

(54) MAGNETIC SENSOR AND METHOD FOR MANUFACTURING SAME

(71) Applicant: TDK Corporation, Tokyo (JP)

(72) Inventors: Hiroki OMURA, Tokyo (JP); Takafumi Kobayashi, Tokyo (JP)

(73) Assignee: TDK Corporation, Tokyo (JP)

(21) Appl. No.: 19/366,766

(22) Filed: Oct. 23, 2025

(30) Foreign Application Priority Data
Nov. 1, 2024 (JP) 2024-192566

(51) Int. Cl. G01R 33/09

(52) U.S. Cl. CPC G01R 33/098

(57) ABSTRACT

A magnetic sensor comprising at least one magnetic field sensing element and at least one first soft magnetic layer. At least one magnetic field sensing element comprises a first magnetically pinned layer, a magnetically free layer whose magnetization direction changes with respect to an external magnetic field, and a first nonmagnetic layer. The first magnetically pinned layer, the magnetically free layer, and the first nonmagnetic layer are arranged in the order of the magnetically free layer, the first nonmagnetic layer, and the first magnetically pinned layer in a first direction. At least one first soft magnetic layer confronts the at least one magnetic field sensing element in the first direction.

### FIELD

This application claims the benefit of Japanese Priority Patent Application No. 2024-192566 filed on November 1, 2024, the entire contents of which are incorporated herein by reference.

The present disclosure relates to a magnetic sensor and a method for manufacturing same.

### BACKGROUND

A magnetic sensor using a magnetoresistive effect generally comprises a magnetically free layer whose magnetization direction changes with respect to an external magnetic field, a magnetically pinned layer whose magnetization direction is pinned, and a nonmagnetic layer located between the magnetically free layer and the magnetically pinned layer. JP2018-6598A describes a magnetic sensor in which the magnetization direction of the magnetically pinned layer is pinned in the stacking direction of the magnetically free layer, the nonmagnetic layer, and the magnetically pinned layer.

### SUMMARY

An object of the present disclosure is to provide a magnetic sensor in which the magnetization direction of a magnetically pinned layer is pinned in the stacking direction of a magnetically free layer, a nonmagnetic layer, and the magnetically pinned layer, and in which the magnetization direction of the magnetically pinned layer tends not to incline from the stacking direction.

The magnetic sensor of the present disclosure comprises at least one magnetic field sensing element and at least one first soft magnetic layer. The at least one magnetic field sensing element comprises a first magnetically pinned layer, a magnetically free layer whose magnetization direction changes with respect to an external magnetic field, and a first nonmagnetic layer. The first magnetically pinned layer, the magnetically free layer, and the first nonmagnetic layer are arranged in the order of the magnetically free layer, the first nonmagnetic layer, and the first magnetically pinned layer in a first direction, and the magnetization direction of the first magnetically pinned layer is pinned in the first direction. The at least one first soft magnetic layer confronts the at least one magnetic field sensing element in the first direction.

The above and other objects, features, and advantages of the present application will become apparent from the following detailed description with reference to the accompanying drawings which illustrate the present application.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the technology.

FIGS. 1A and 1B are schematic drawings of a magnetic sensor according to a first example embodiment.

FIG. 2 is a schematic drawing of a magnetic sensor according to a second example embodiment.

FIG. 3 is a schematic drawing of a magnetic sensor according to a third example embodiment.

FIG. 4 is a schematic drawing of a magnetic sensor according to a fourth example embodiment.

FIG. 5 is a schematic drawing of a magnetic sensor according to a fifth example embodiment.

FIGS. 6A-6C are schematic drawings of magnetic sensors according to a sixth example embodiment and comparative examples.

FIG. 7 is a schematic drawing of a magnetic sensor according to a seventh example embodiment.

FIG. 8 is a schematic drawing of a magnetic sensor according to an eighth example embodiment.

FIG. 9 is a schematic drawing of a magnetic sensor according to a ninth example embodiment.

### DETAILED DESCRIPTION

In the following, some example embodiments and modification examples of the technology are described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions.

In the magnetic sensor described in JP2018-6598A, the magnetization direction of a magnetically pinned layer is pinned in the stacking direction, but the magnetization direction of the magnetically pinned layer may incline from the stacking direction due to an external magnetic field orthogonal to the stacking direction. The inclination of the magnetization direction of the magnetically pinned layer may cause a decrease in the output of the magnetic sensor.

Some example embodiments of the present disclosure are described below with reference to the drawings. In the following description and drawings, the direction in which the plurality of layers of laminated body 6 is stacked (first direction) is referred to as the Z-direction. The direction from laminated body 6 toward upper electrode layer 5 is referred to as the +Z-direction. The direction from laminated body 6 toward lower electrode layer 7 or the substrate is referred to as the –Z-direction. A direction orthogonal to the Z-direction is referred to as the X-direction. Although the X-direction is indicated in the drawings for convenience, the X-direction may be any direction orthogonal to the Z-direction. Unless otherwise described, white arrows in the drawings indicate the magnetization directions of first magnetically pinned layer 63 and second magnetically pinned layer 65. Heavy arrowed lines indicate the magnetization direction of magnetically free layer 61 in the absence of an external magnetic field (hereinafter referred to as the “zero magnetic field state”). Dashed lines with arrows conceptually indicate magnetic flux (an external magnetic field).

### First example embodiment

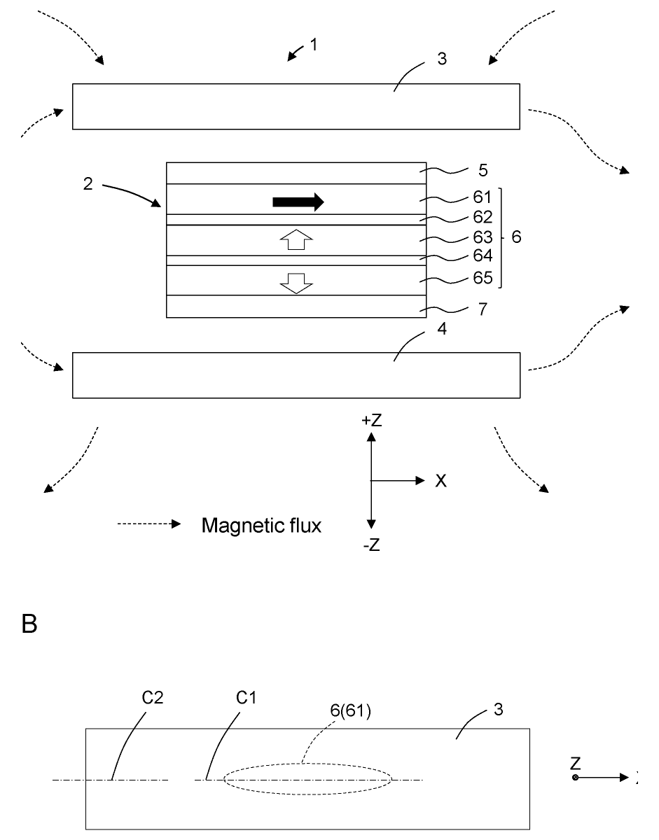

FIGS. 1A and 1B show the schematic structure of magnetic sensor 1 according to a first example embodiment. FIG. 1A is a front view of magnetic sensor 1. FIG. 1B is a top view of magnetic sensor 1 viewed from the Z-direction. Magnetic sensor 1 may comprise magnetic field sensing element 2 and first and second soft magnetic layers 3 and 4 that sandwich magnetic field sensing element 2 in the Z-direction. Magnetic field sensing element 2 may comprise a silicon substrate (not shown), laminated body 6, and upper and lower electrode layers 5 and 7 that supply a sense current to laminated body 6. Upper electrode layer 5, laminated body 6, and lower electrode layer 7 may be arranged on the substrate in the order of upper electrode layer 5, laminated body 6, and lower electrode layer 7 in the –Z-direction. Although not shown in the figure, other layers may be provided between lower electrode layer 7 and the substrate, and lower electrode layer 7 is separated from the substrate. Upper electrode layer 5 and lower electrode layer 7 can be formed by a multilayer film or the like made of a conducting material such as Ta, Cu, and Ru. First soft magnetic layer 3 and second soft magnetic layer can be formed of, for example, NiFe.

Laminated body 6 may comprise magnetically free layer 61, first nonmagnetic layer 62, first magnetically pinned layer 63, second magnetically pinned layer 65, and intermediate layer 64. These layers may be arranged in the order of magnetically free layer 61, first nonmagnetic layer 62, first magnetically pinned layer 63, intermediate layer 64, and second magnetically pinned layer 65 in the –Z-direction from upper electrode layer 5 to lower electrode layer 7, and adjacent layers may be in contact with each other. These layers may also be stacked in the opposite direction. Specifically, they may be arranged in the order of second magnetically pinned layer 65, intermediate layer 64, first magnetically pinned layer 63, first nonmagnetic layer 62, and magnetically free layer 61 in the –Z-direction from upper electrode layer 5 toward lower electrode layer 7.

Magnetically free layer 61 is a magnetic layer whose magnetization direction changes with respect to an external magnetic field. Magnetically free layer 61 can be made of a ferromagnetic material such as Ni, Fe, Co, an alloy comprising two or more of these, or an amorphous alloy made by adding B or Si to the alloy. The magnetization direction of magnetically free layer 61 may be oriented orthogonally to the Z-direction in the zero magnetic field state.

First nonmagnetic layer 62 may comprise an insulating layer such as MgO or Al₂O₃. Magnetic field sensing element 2 of this example embodiment functions as a tunnel magnetoresistive device (TMR device). First nonmagnetic layer 62 may comprise a nonmagnetic metal layer such as copper or silver. In this case, magnetic field sensing element 2 functions as a giant magnetoresistive element (GMR element). A TMR element may easily provide higher output than a GMR element.

First magnetically pinned layer 63 is a magnetic layer whose magnetization direction is pinned in the Z-direction. First magnetically pinned layer 63 may be magnetically coupled with second magnetically pinned layer 65 by synthetic antiferromagnetic coupling through intermediate layer 64. The magnetization direction of first magnetically pinned layer 63 may be pinned in the direction opposite to the magnetization direction of second magnetically pinned layer 65. First magnetically pinned layer 63 and second magnetically pinned layer 65 can be formed of multilayer films composed of Co film and Pt film, or of materials with strong perpendicular magnetic anisotropy, such as multilayer films of Co films and Pd films or multilayer films of Co films and Ni films. Intermediate layer 64 may be made of a nonmagnetic metal such as ruthenium that gives rise to RKKY (Ruderman-Kittel-Kasuya-Yosida) coupling. The multilayer film comprising first magnetically pinned layer 63, intermediate layer 64, and second magnetically pinned layer 65 is also referred to as a SAF (synthetic antiferromagnetic) structure. Since the magnetization direction of first magnetically pinned layer 63 is opposite to the magnetization direction of second magnetically pinned layer 65, the leakage magnetic field applied to magnetically free layer 61 from first magnetically pinned layer 63 can be suppressed. The amount of magnetization of first magnetization layer 63 and the amount of magnetization of second magnetically pinned layer 65 can be made the same level. In FIG. 1A, first magnetically pinned layer 63 is magnetized in the +Z-direction and second magnetically pinned layer 65 is magnetized in the –Z-direction. However, first magnetically pinned layer 63 may also be magnetized in the –Z-direction and second magnetically pinned layer 65 in the +Z-direction.

When an external magnetic field having a component in the Z-direction is applied to magnetically free layer 61, the magnetization direction of magnetically free layer 61 inclines in the Z-direction. Accordingly, the angle between the magnetization direction of magnetically free layer 61 and the magnetization direction of first magnetically pinned layer 63 changes, and the electrical resistance of laminated body 6 changes due to the magnetoresistance effect. By detecting the change in electrical resistance of laminated body 6, the intensity of the Z-direction component of the external magnetic field can be measured. In this way, magnetic sensor 1 of this example embodiment detects magnetic fields in the Z-direction.

First soft magnetic layer 3 and second soft magnetic layer 4 may face magnetic field sensing element 2 (or laminated body 6) in the Z-direction. Magnetic field sensing element 2 (or laminated body 6) may be positioned between first soft magnetic layer 3 and second soft magnetic layer 4 in the Z-direction. One of first soft magnetic layer 3 and second soft magnetic layer 4 may be omitted. First soft magnetic layer 3 and second soft magnetic layer 4 attenuate external magnetic fields in the X-direction applied to laminated body 6 by absorbing the magnetic flux in the X-direction. The magnetization direction of first magnetically pinned layer 63 may be pinned in the Z-direction. When a strong magnetic field is applied to first magnetically pinned layer 63 from a direction other than the Z-direction, the magnetization direction of first magnetically pinned layer 63 inclines from the Z-direction, and this inclination may decrease the output of magnetic sensor 1. The magnetization direction of magnetically free layer 61 is determined by the composite magnetic field of the magnetic fields in the Z-direction and magnetic fields in directions other than the Z-direction. Therefore, when the intensity of the magnetic fields applied from directions other than the Z-direction fluctuates significantly, the inclination of the magnetization direction of magnetically free layer 61 with respect to the Z-direction may change even though the magnetic field intensity in the Z-direction is constant, and the possibility then arises that the sensitivity of magnetic sensor 1 will fluctuate. In this example embodiment, first soft magnetic layer 3 and second soft magnetic layer 4 act as a shield against magnetic fields applied from directions other than the Z-direction and thus reduce this possibility.

As shown in FIG. 1B, laminated body 6 including magnetically free layer 61 has, in any cross section orthogonal to the Z-direction, an elliptical shape with long axis C1. The shape of laminated body 6 is not limited provided the shape has long axis C1 and may have any shape, such as a rectangle, a rectangle with semicircular sides at both short sides, or a rectangle with each corner rounded or cut off. Because laminated body 6 has long axis C1, a shape anisotropic magnetic field parallel to long axis C1 is produced in magnetically free layer 61. This magnetic field acts as a bias magnetic field for magnetically free layer 61. The bias magnetic field is a magnetic field that directs the magnetization direction of magnetically free layer 61 in a predetermined direction in a zero magnetic field state, and the direction and intensity are constant. The bias magnetic field causes magnetically free layer 61 to be magnetized in a direction parallel to long axis C1 in the zero magnetic field state. Since generation of a large number of magnetic domains in magnetically free layer 61 is suppressed, the output to the magnetic field in the Z-direction is more stable.

On the other hand, when an external magnetic field is applied in the same direction as the bias magnetic field, the magnetization direction of magnetically free layer 61 is less likely to tilt in the Z-direction and sensitivity to a magnetic field in the Z-direction decreases. When an external magnetic field is applied in the direction opposite to the bias magnetic field, the magnetization direction of the magnetically free layer 61 is more likely to tilt in the Z-direction, and sensitivity to a magnetic field in the Z-direction increases. As a result, the output signal tends to become unstable with respect to the direction of the external magnetic field. Therefore, the application of an external magnetic field to the magnetically free layer 61 in the same direction as or in the opposite direction to the bias magnetic field may be suppressed to the greatest extent possible. The external magnetic fields referred to here are external magnetic fields other than the one to be detected, and such external magnetic fields can generally vary in direction and intensity over time. External magnetic fields are magnetic fields in directions other than the Z-direction and do not include the bias magnetic field.

Generally, the shielding function of a magnetic body is caused by the magnetization of the magnetic body by an external magnetic field. Specifically, when an external magnetic field is applied, magnetic poles are generated at the ends of the magnetic body in the direction of the external magnetic field. Part of the magnetic field generated by the magnetic poles functions to cancel the external magnetic field, thereby shielding the vicinity of the magnetic body from the external magnetic field. The magnetic poles are generated by a relatively weak external magnetic field in the long-axis direction (easy magnetization axis direction) of the magnetic body, and the magnetic body exhibits strong shielding properties (having the effect of canceling out the external magnetic field). In contrast, in the short-axis direction (hard-to-magnetize axis direction) of the magnetic material, the shielding property is relatively weak because the magnetic body is not easily magnetized and magnetic poles are not generated.

In this example embodiment, at least one of first soft magnetic layer 3 and second soft magnetic layer 4 has long axis C2. The direction of the bias magnetic field applied to magnetically free layer 61 can be made parallel to long axis C2 of at least one of first soft magnetic layer 3 and second soft magnetic layer 4. In other words, magnetically free layer 61 has long axis C1, at least one of first soft magnetic layer 3 and second soft magnetic layer 4 has long axis C2, and long axis C1 and long axis C2 can be made parallel. Alternatively, both first soft magnetic layer 3 and second soft magnetic layer 4 have long axes C2 in the same direction, and the direction of the bias magnetic field applied to magnetically free layer 61 can be made parallel to long axes C2 of first soft magnetic layer 3 and second soft magnetic layer 4. In other words, magnetically free layer 61 has long axis C1, both first soft magnetic layer 3 and second soft magnetic layer 4 have long axes C2 in the same direction, and long axes C1 and C2 can be made parallel. The shapes of first soft magnetic layer 3 and second soft magnetic layer 4 are also not limited provided they have long axes C2, and may have any shape, such as a rectangle, a rectangle having semicircular short sides on both sides, or a rectangle having corners that are rounded or cut off.

Means for applying the bias magnetic field is not limited to the shape of magnetically free layer 61 itself and may be a magnet installed on the side of magnetically free layer 61 or a magnet installed outside magnetic sensor 1. Further, means for applying a bias magnetic field may also be omitted. In this case, magnetically free layer 61 can have a shape that lacks a long axis (for example, a circle or square) as viewed from the Z-direction, and the magnetization direction need not be aligned in the zero magnetic field state. First soft magnetic layer 3 and second soft magnetic layer 4 may also have shapes that lack a long axis (for example, a circle or square) as viewed from the Z-direction.

First soft magnetic layer 3 and second soft magnetic layer 4 also have an effect of strengthening the magnetic field in the Z-direction. The magnetic flux around first soft magnetic layer 3 (or second soft magnetic layer 4) flows toward first soft magnetic layer 3 (or second soft magnetic layer 4) and is emitted from second soft magnetic layer 4 (or first soft magnetic layer 3) to the surroundings. First soft magnetic layer 3 and second soft magnetic layer 4 have a magnetism-collection effect on the magnetic field in the Z-direction and act as a yoke, thereby increasing the output of magnetic sensor 1. Thus, in this example embodiment, first soft magnetic layer 3 and second soft magnetic layer 4 act as both a shield and a yoke depending on the direction of the magnetic field. For example, protecting recorded data is crucial in a magnetoresistive memory (MRAM), and the soft magnetic bodies around the memory act as shields regardless of the direction of the magnetic field. The function of the soft magnetic layers (first soft magnetic layer 3 and second soft magnetic layer 4) of magnetic sensor 1 in this example embodiment differs greatly from other applications using the magnetoresistive effect.

When a magnetic sensor of the related art in which the magnetization direction of a magnetically free layer changes in an in-plane direction (X-direction) is used together with a yoke to detect a Z-direction magnetic field, the Z-direction magnetic field must be bent in the in-plane direction by the yoke and applied to the magnetically free layer. For this reason, a laminated body is displaced with respect to the yoke in the Z-direction. Because a Z-direction magnetic field is detected without changing its direction In this example embodiment, first soft magnetic layer 3 and second soft magnetic layer 4 can be placed directly above or directly below laminated body 6 in the Z-direction. Specifically, the center of magnetically free layer 61 may overlap with first soft magnetic layer 3 and second soft magnetic layer 4 in the Z-direction, and this configuration facilitates the realization of a more compact magnetic sensor 1.

### Second example embodiment

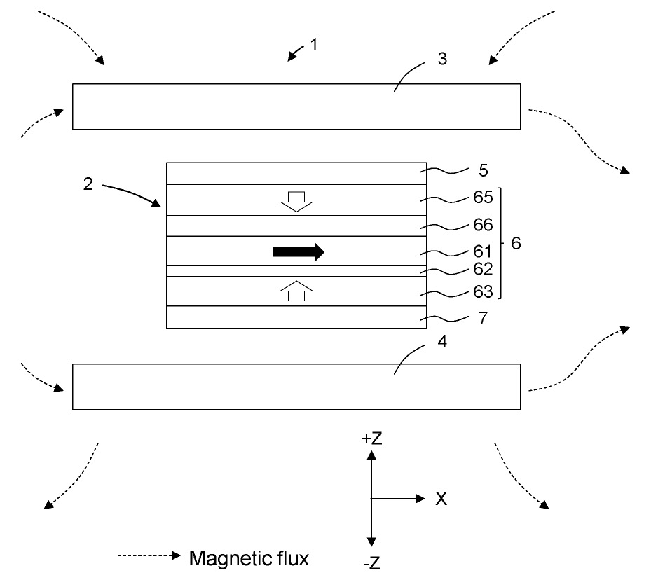

FIG. 2 shows the schematic structure of magnetic sensor 1 according to a second example embodiment. Explanation of structure and effect that are the same as in the first example embodiment is omitted from the following description. Laminated body 6 may comprise magnetically free layer 61, first nonmagnetic layer 62, first magnetically pinned layer 63, second magnetically pinned layer 65, and second nonmagnetic layer 66. These layers may be arranged in the order of second magnetically pinned layer 65, second nonmagnetic layer 66, magnetically free layer 61, first nonmagnetic layer 62, and first magnetically pinned layer 63, and adjacent layers may be in contact with each other in the –Z-direction from upper electrode layer 5 to lower electrode layer 7. These layers may also be stacked in the opposite direction. Specifically, they may be arranged in the order of first magnetically pinned layer 63, first nonmagnetic layer 62, magnetically free layer 61, second nonmagnetic layer 66, and second magnetically pinned layer 65 in the –Z-direction from upper electrode layer 5 to lower electrode layer 7. Magnetically free layer 61, first nonmagnetic layer 62, first magnetically pinned layer 63, and second magnetically pinned layer 65 can have the same structure as in the first example embodiment. Second nonmagnetic layer 66 is provided to magnetically separate magnetically free layer 61 and second magnetically pinned layer 65 and therefore is not limited provided it is a nonmagnetic layer. Second nonmagnetic layer 66 may be formed of either a metal such as copper or an insulator such as Al₂O₃.

The magnetization direction of second magnetically pinned layer 65 is pinned in a direction opposite to the magnetization direction of first magnetically pinned layer 63. As a result, leakage magnetic field applied to magnetically free layer 61 can also be suppressed in this example embodiment. In FIG. 2, first magnetically pinned layer 63 may be magnetized in the +Z-direction and second magnetically pinned layer 65 may be magnetized in the –Z-direction. Alternatively, first magnetically pinned layer 63 may be magnetized in the –Z-direction and second magnetically pinned layer 65 may be magnetized in the +Z-direction. In order to make the magnetization directions of first magnetically pinned layer 63 and second magnetically pinned layer 65 opposite to each other, anisotropic magnetic field Hk1 of first magnetically pinned layer 63 and anisotropic magnetic field Hk2 of second magnetically pinned layer 65 can be made different from each other. For example, if Hk1 > Hk2, magnetic field H1 in the Z-direction that is greater than Hk1 is first applied to first magnetically pinned layer 63 and second magnetically pinned layer 65. Since H1 > Hk1 > Hk2, first magnetically pinned layer 63 and second magnetically pinned layer 65 are magnetized in the same direction. Next, magnetic field H2 that satisfies the relation Hk1 > H2 > Hk2 and that is in the direction opposite to magnetic field H1 is applied to first magnetically pinned layer 63 and second magnetically pinned layer 65. The magnetization direction of first magnetically pinned layer 63 remains unchanged, and only the magnetization direction of second magnetically pinned layer 65 reverses.

### Third example embodiment

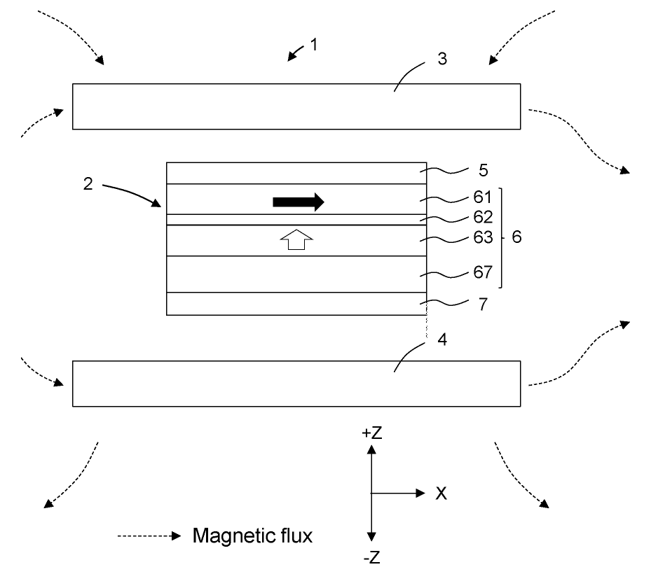

FIG. 3 shows the schematic structure of magnetic sensor 1 according to a third example embodiment. Explanation of structure and effect that are the same as in the first embodiment is omitted from the following description. Laminated body 6 may comprise magnetically free layer 61, first nonmagnetic layer 62, first magnetically pinned layer 63, and antiferromagnetic layer 67. These layers may be arranged in the order of magnetically free layer 61, first nonmagnetic layer 62, first magnetically pinned layer 63, and antiferromagnetic layer 67, and adjacent layers are in contact with each other in the –Z-direction from upper electrode layer 5 to lower electrode layer 7. These layers may also be stacked in the opposite direction. Specifically, the layers may be arranged in the order of antiferromagnetic layer 67, first magnetically pinned layer 63, first nonmagnetic layer 62, and magnetically free layer 61 in the –Z-direction from upper electrode layer 5 to lower electrode layer 7. Magnetically free layer 61, first nonmagnetic layer 62, and first magnetically pinned layer 63 may have the same structure as in the first example embodiment. Antiferromagnetic layer 67 can be formed of IrMn or of antiferromagnetic materials such as PtMn and FeRh.

Magnetization of first magnetically pinned layer 63 may be performed by applying an external magnetic field while annealing (heating). First magnetically pinned layer 63 is exchange-coupled with antiferromagnetic layer 67 and pinned in the same direction as the magnetization direction during annealing. If a strong Z-direction magnetic field is applied in the direction opposite to the magnetization direction of first magnetically pinned layer 63, the magnetization direction of first magnetically pinned layer 63 may be temporarily reversed. If the magnetization direction of first magnetically pinned layer 63 remains reversed, the slope of the output curve may invert (e.g., a right-upward output curve may change to a right-downward output curve). However, upon attaining the zero magnetic field state, the magnetization direction of first magnetically pinned layer 63 returns to the original direction. Therefore, the magnetization direction of first magnetically pinned layer 63 in the zero magnetic field state is easily stabilized, and output reversal is unlikely to occur. In FIG. 3, antiferromagnetic layer 67 and first magnetically pinned layer 63 are magnetized in the +Z-direction, but these layers may also be magnetized in the –Z-direction.

### Fourth example embodiment

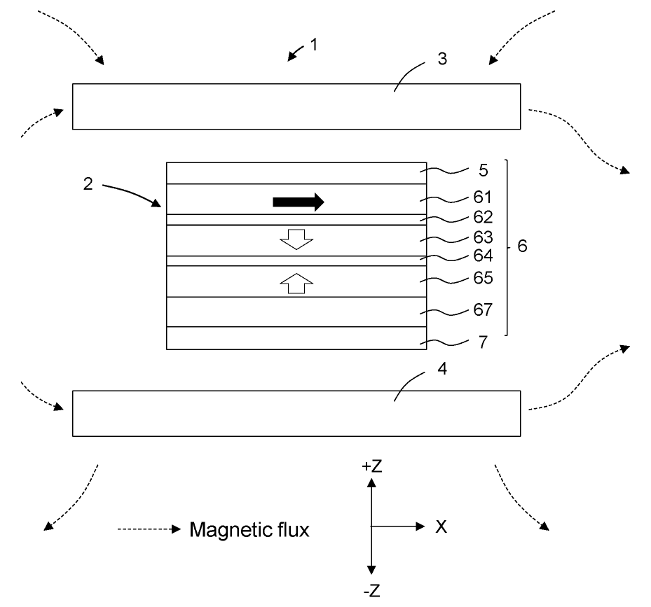

FIG. 4 shows the schematic structure of magnetic sensor 1 according to a fourth example embodiment. Explanation of structure and effect that are the same as in the first example embodiment is omitted from the description. Laminated body 6 of this example embodiment may have a configuration that is a combination of the first example embodiment and third example embodiment. Laminated body 6 may comprise magnetization free-layer 61, first nonmagnetic layer 62, first magnetically pinned layer 63, intermediate layer 64 made of a nonmagnetic metal that generates RKKY coupling such as ruthenium, second magnetically pinned layer 65, and antiferromagnetic layer 67. These layers may be arranged in the order of magnetically free layer 61, first nonmagnetic layer 62, first magnetically pinned layer 63, intermediate layer 64, second magnetically pinned layer 65, and antiferromagnetic layer 67, and adjacent layers are in contact with each other in the –Z-direction from upper electrode layer 5 to lower electrode layer 7. These layers may also be stacked in the opposite direction. Specifically, they may be arranged in the order of antiferromagnetic layer 67, second magnetically pinned layer 65, intermediate layer 64, first magnetically pinned layer 63, first nonmagnetic layer 62, and magnetically free layer 61 in the –Z-direction from upper electrode layer 5 to lower electrode layer 7.

Due to the SAF structure, the magnetization direction of first magnetically pinned layer 63 is pinned in the direction opposite to the magnetization direction of second magnetically pinned layer 65. Further, the magnetization direction of second magnetically pinned layer 65 is pinned in the same direction as the magnetization direction during annealing by exchange coupling with antiferromagnetic layer 67. This example embodiment achieves the effects of both the first and third example embodiments. Specifically, not only is the SAF structure able to suppress the leakage magnetic field applied to magnetically free layer 61, but antiferromagnetic layer 67 stabilizes the magnetization direction of second magnetically pinned layer 65 in the zero magnetic field state.

### Fifth example embodiment

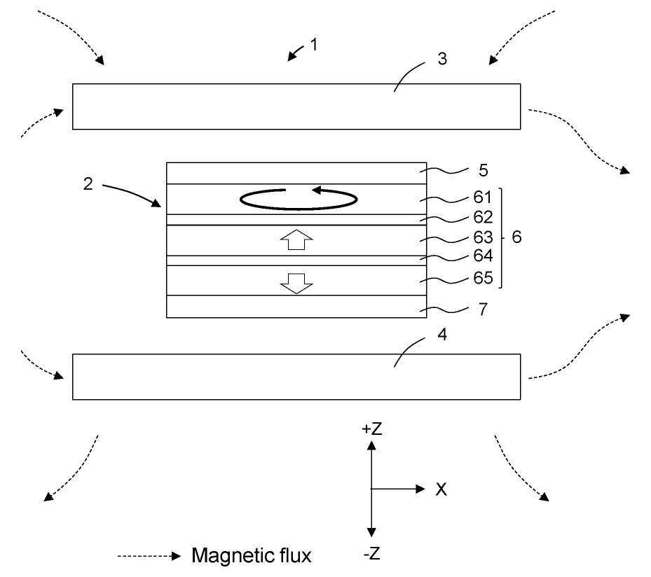

FIG. 5 shows the schematic structure of magnetic sensor 1 according to a fifth example embodiment. Explanation of structure and effect that are the same as in the first example embodiment is omitted from the description. The structure of laminated body 6 in this example embodiment is similar to that of the first example embodiment, but in the zero magnetic field state, the magnetization direction of magnetically free layer 61 has a vortex shape in a plane perpendicular to the Z-direction. The magnetization state of magnetically free layer 61 in the zero magnetic field state depends on the balance between the exchange energy and the static magnetic energy of magnetically free layer 61. In general, the vortex shape is more likely to occur when the saturation magnetization is large. In the zero magnetic field state, the center of the vortex shape, which is referred to as the core, is located at the center of magnetically free layer 61, and the magnetization direction describes concentric circles around the core. When an external magnetic field in the Z-direction is applied, the magnetization direction tilts overall in the Z-direction, resulting in the same magnetoresistance effect as in the first example embodiment. In this example embodiment, magnetically free layer 61 has a vortex shape in the zero magnetic field state, and as a result, fluctuations in sensitivity are easily suppressed when a magnetic field in a direction other than the Z-direction is applied. This example embodiment can be combined with the second to fourth example embodiments. Specifically, the magnetization direction of magnetically free layer 61 of the second to fourth example embodiments can have a vortex shape.

### Sixth example embodiment

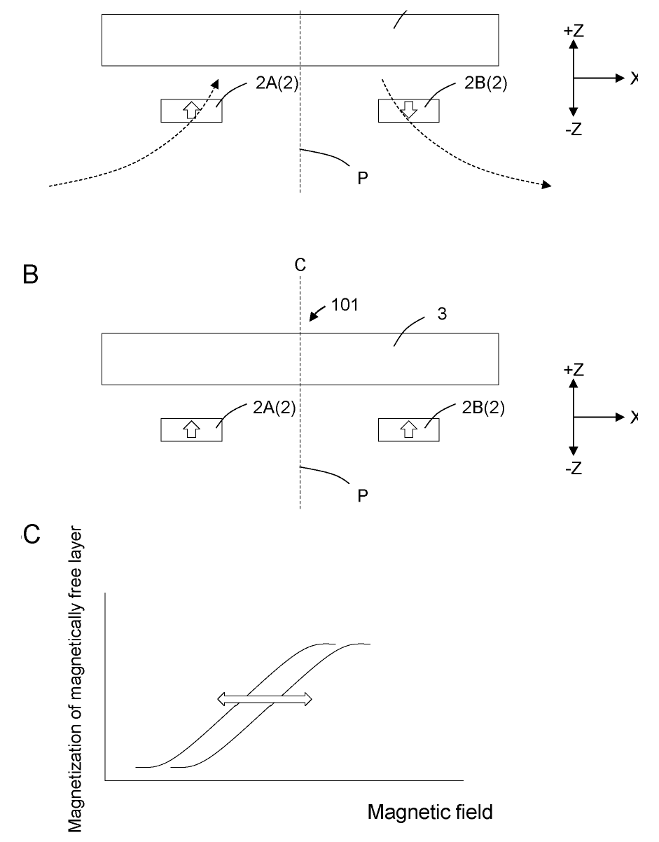

FIG. 6A shows the schematic structure of magnetic sensor 1 according to a sixth example embodiment. Explanation of structure and effect that are the same as in the first example embodiment is omitted from this description. Magnetic sensor 1 in this example embodiment may comprise a plurality of magnetic field sensing elements 2 of the fifth example embodiment, i.e., magnetic field sensing elements 2 in which the magnetization direction of magnetically free layer 61 has a vortex shape in the zero magnetic field state. The structure of each of the plurality of magnetic field sensing elements 2 may be the same as the magnetic field sensing element 2 of the fifth example embodiment. The plurality of magnetic field sensing elements 2 is connected in series. The number of the plurality of magnetic field sensing elements 2 is not limited, but in FIG. 6A, two magnetic field sensing elements 2 (hereinafter referred to as first magnetic field sensing element 2A and second magnetic field sensing element 2B) are shown for convenience. The plurality of magnetic field sensing elements 2 confront single first soft magnetic layer 3 in the Z-direction. White arrows indicate the magnetization directions of the cores in the zero magnetic field state of magnetically free layers 61.

FIG. 6B shows the schematic structure of magnetic sensor 101 according to a comparative example. FIG. 6C shows a magnetization curve of magnetically free layer 61. The magnetization direction of the core of magnetically free layer 61 may be either in the +Z-direction or in the –Z-direction in the zero magnetic field state. The magnetization curve of magnetically free layer 61 (the curve that is produced when the magnetic field intensity is plotted on the horizontal axis and magnetization is plotted on the vertical axis) shifts to the left or right depending on the orientation of the core. For example, if the magnetization curve shifts to the left when the core is magnetized in the +Z-direction, the magnetization curve shifts to the right when the core is magnetized in the –Z-direction. These magnetic characteristics reduce the accuracy of the output of magnetic sensor 1.

In this example embodiment, the magnetization directions of the cores in first magnetic field sensing elements 2A may be opposite to the magnetization directions of the cores in second magnetic field sensing elements 2B (one portion of and the remainder of the plurality of magnetic field sensing elements 2). In this way, the shift of the magnetization curve of magnetically free layers 61 of first magnetic field sensing elements 2A cancels the shift of the magnetization curve of magnetically free layers 61 of second magnetic field sensing elements 2B, thereby improving the accuracy of the output of magnetic sensor 1. As can be understood, the same number of magnetic field sensing elements 2 can be arranged in the left region as in right region of first soft magnetic layer 3 in FIG. 6A. More generally, the same number of magnetic field sensing elements 2 can be arranged on both sides of plane P that contains centerline C that is parallel to the Z-direction of first soft magnetic layer 3.

To make the magnetization directions of the cores of first magnetic field sensing elements 2A and the magnetization direction of the cores of second magnetic field sensing elements 2B opposite to each other, an external magnetic field can be applied in the X-direction. An external magnetic field in the X-direction may be bent in the +Z-direction by first soft magnetic layer 3. A magnetic field including a component in the +Z-direction may be applied to first magnetic field sensing elements 2A. A magnetic field including a component in the –Z-direction is applied to second magnetic field sensing elements 2B. If the Z-direction components of the external magnetic fields is sufficiently large, the cores disappear temporarily. When the external magnetic fields are removed, the cores reappear. The magnetization directions of the cores are determined by the Z-direction component of the last applied magnetic field. In the example shown in FIG. 6A, the magnetization directions of the cores of first magnetic field sensing elements 2A are in the +Z-direction, while the magnetization directions of the cores of second magnetic field sensing elements 2B are in the –Z-direction.

Plane P may be oriented in any direction as long as it is parallel to the Z-direction. By applying an external magnetic field from a direction orthogonal to plane P, a magnetic field containing a component in the +Z-direction can be applied to one portion of magnetic field sensing elements 2 and a magnetic field containing a component in the –Z-direction can be applied to the remainder of magnetic field sensing elements 2. Plane P can also be determined by the arrangement of the plurality of magnetic field detection elements 2. Specifically, plane P can be determined such that the plurality of magnetic field detection elements 2 is bisected by plane P. FIGS. 6A–6B show only first soft magnetic layer 3. However, when first soft magnetic layer 3 and second soft magnetic layer 4 are provided, first magnetic field sensing elements 2A and second magnetic field sensing elements 2B can be placed at positions displaced from the center in the Z-direction of first soft magnetic layer 3 and the second soft magnetic layer 4. This configuration allows magnetic fields including a component in the +Z-direction and a component in the –Z-direction to be applied to each of first magnetic field sensing elements 2A and second magnetic field sensing elements 2B.

### Seventh example embodiment

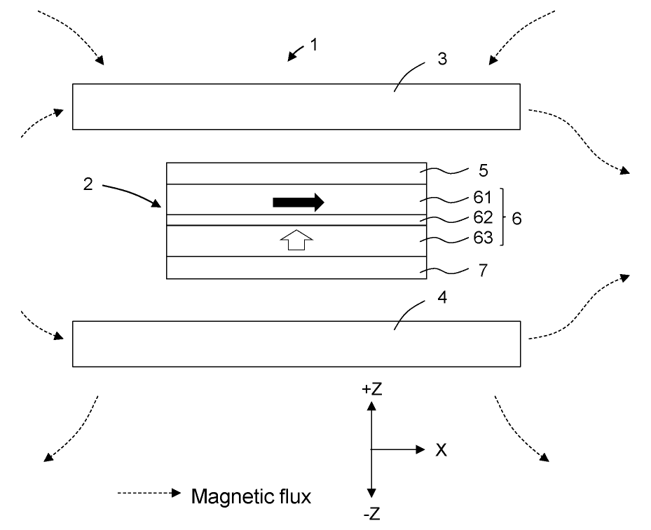

FIG. 7 shows the schematic structure of magnetic sensor 1 according to a seventh example embodiment. Explanation of structure and effects that are the same as in the first example embodiment is omitted from this description. Laminated body 6 may comprise magnetically free layer 61, first nonmagnetic layer 62, and first magnetically pinned layer. These layers may be arranged in the order of magnetically free layer 61, first nonmagnetic layer 62, and first magnetically pinned layer 63, and adjacent layers are in contact with each other in the –Z-direction from upper electrode layer 5 to lower electrode layer 7. These layers may also be stacked in the opposite direction. Specifically, they may also be arranged in the order of first magnetically pinned layer 63, first nonmagnetic layer 62, and magnetically free layer 61 in the –Z-direction from upper electrode layer 5 to lower electrode layer 7. This example embodiment omits second magnetically pinned layer 65 and second nonmagnetic layer 66 of the first example embodiment, but the configuration is otherwise the same as in the first example embodiment. This example embodiment simplifies the structure of laminated body 6 and reduces the cost of magnetic sensor 1.

### Eighth example embodiment

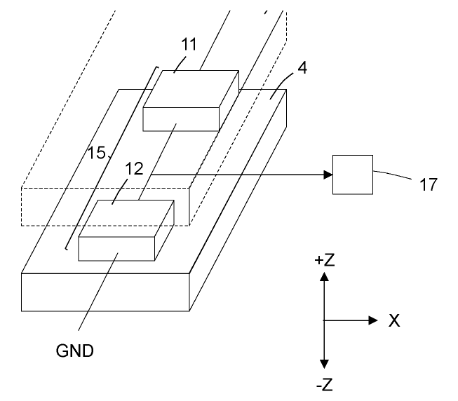

FIG. 8 shows the schematic structure of magnetic sensor 1 according to an eighth example embodiment. In magnetic sensor 1 of this example embodiment, magnetic field sensing elements 2 of each of the above-described example embodiments are combined as a half bridge. Magnetic sensor 1 may comprise first and second element units 11 and 12 each comprising at least one magnetic field sensing element 2. In one example, first and second element units 11 and 12 each comprise an array of a plurality of magnetic field sensing elements 2 connected in series. First and second element units 11 and 12 may be connected in series to form group 15. One end of group 15 may be connected to power supply VDD and other end may be grounded (GND). Magnetic sensor 1 may comprise output 17 located between first element unit 11 and second element unit 12. The magnetization direction of first magnetically pinned layer 63 of first element unit 11 and the magnetization direction of first magnetically pinned layer 63 of second element unit 12 are opposite to each other. First soft magnetic layer 3 (indicated by dashed lines for convenience) and second soft magnetic layer 4 may cover all of first and second element units 11 and 12 in the Z-direction, but first and second element units 11 and 12 may also be covered individually, or individual magnetic field sensing elements 2 may be covered individually.

In the eighth example embodiment, magnetic sensor 1 (third and fourth example embodiments) in which magnetic field sensing element 2 is equipped with antiferromagnetic layer 67 can be manufactured using laser annealing. Specifically, in the case of, for example, the film configuration shown in FIG. 3, a magnetic field is applied in the Z-direction (in the first direction) while irradiating first element unit 11 with a laser beam to magnetize first magnetically pinned layer 63 of first element unit 11, and the magnetization direction is then pinned by exchange coupling with antiferromagnetic layer 67. Next, for example, a magnetic field in the direction (in the second direction) opposite to the magnetic field applied to first element unit 11 is applied to second element unit 12 while irradiating second element unit 12 with a laser beam to magnetize first magnetically pinned layer 63 of second element unit 12, and the magnetization direction is then pinned by exchange coupling with antiferromagnetic layer 67. In the case of the film configuration shown in FIG. 4, second magnetically pinned layer 65 is magnetized and the magnetization direction is pinned by exchange coupling with antiferromagnetic layer 67. In laser annealing, laser beams are irradiated at multiple positions. Considering the formation accuracy of the element unit or the like, the intervals between the irradiation positions of the laser beams should be 5 μm or more and preferably 10 μm or more.

Although laser annealing is performed to magnetize the magnetically pinned layer in this example embodiment, the heating method is not limited to laser light if first element unit 11 and second element unit 12 can be locally heated. For example, wiring for heating may be provided near first element unit 11 and second element unit 12, and first element unit 11 and second element unit 12 may then be heated by energizing the wiring for heating and generating heat in the wiring for heating.

### Ninth example embodiment

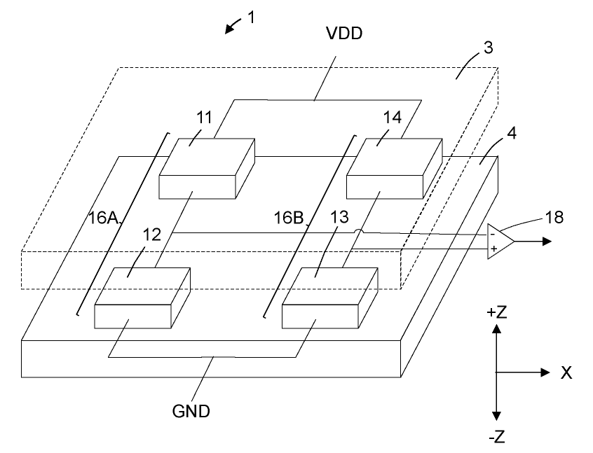

FIG. 9 shows the schematic structure of magnetic sensor 1 according to a ninth example embodiment. In magnetic sensor 1 of this example embodiment, magnetic field sensing elements 2 of each of the above-described example embodiments are combined as a full bridge. Magnetic sensor 1 may comprise first to fourth element units 11–14 each having at least one magnetic field sensing element 2. In one example, first to fourth element units 11–14 each have an array of a plurality of magnetic field sensing elements 2 connected in series. First and second element units 11 and 12 may be connected in series to form first group 16A. Third and fourth element units 11 and 12 may be connected in series to form second group 16B. One ends of each of first and second groups 16A and 16B may be connected to power supply VDD and the other ends may be grounded (GND). First element unit 11 and fourth element unit 14 are located on the power-supply-VDD side, and second element unit 12 and third element unit 13 are located on the ground side (GND). Magnetic sensor 1 may comprise a differentiator 18 for determining the difference between the output between first element unit 11 and second element unit 12 and the output between third element unit 13 and fourth element unit 14. First magnetically pinned layer 63 of first element unit 11 and first magnetically pinned layer 63 of third element unit 13 have the same magnetization direction. The magnetization directions of first magnetically pinned layers 63 of second element unit 12 and fourth element unit 14 are opposite to the magnetization directions of first magnetically pinned layers 63 of first element unit 11 and third element unit 13. First soft magnetic layer 3 (indicated by dashed lines for convenience) and second soft magnetic layer 4 cover all of first to fourth element units 11–14 in the Z-direction, but first to fourth element units 11–14 may also be covered individually, or individual magnetic field sensing elements 2 may each be covered individually.

Voltage drop at each of element units 11–14 is approximately proportional to the electrical resistance of element units 11–14. Therefore, if the electrical resistance of first to fourth element units 11–14 is R1–R4, respectively, midpoint voltage V1 = R2 / (R1 + R2) x VDD and midpoint voltage V2 = R3 / (R3 + R4) x VDD. By obtaining the difference between V1 and V2 of midpoint voltages V1 and V2 by differentiator 18, sensitivity can be achieved that is twice as high as when detecting midpoint voltages V1 and V2. Even if midpoint voltages V1 and V2 are offset, the effect of the offset can be eliminated by detecting the difference.

In the ninth example embodiment, magnetic sensor 1 (third and fourth example embodiments) in which magnetic field sensing element 2 is equipped with antiferromagnetic layer 67 can be manufactured using laser annealing. Specifically, in the case of, for example, the film configuration shown in FIG. 3, a magnetic field is applied in the Z-direction (in the first direction) while irradiating first and third element units 11 and 13 with a laser beam to magnetize first magnetically pinned layers 63 of first element unit 11 and third element unit 13, and the magnetization directions are then pinned by exchange coupling with antiferromagnetic layers 67. Next, a magnetic field that is, for example, in the direction (in the second direction) opposite to the magnetic field applied to first and third element units 11 and 13 is applied to second element unit 12 and fourth element unit 14 while irradiating second element unit 12 and fourth element unit 14 with a laser beam to magnetize first magnetically pinned layers 63 of second element unit 12 and fourth element unit 14, and the magnetization directions are then pinned by exchange coupling with antiferromagnetic layers 67. In the case of the film configuration shown in FIG. 4, second magnetically pinned layer 65 is magnetized and the magnetization direction is pinned by exchange coupling with antiferromagnetic layer 67. The heating method is again not limited to laser light in this example embodiment. For details, refer to the eighth example embodiment. In this example embodiment as well, the intervals between the irradiation positions of the laser beams should be 5 μm or more and preferably 10 μm or more.

In the eighth and ninth example embodiment, the above-described SAF structure can also be used to make the magnetization directions of first magnetically pinned layers 63 of some element units opposite to the magnetization directions of the other element units. For example, when magnetic field sensing element 2 of the first example embodiment is used in the eighth example embodiment, the thickness of first magnetically pinned layer 63 can be made greater than in second magnetically pinned layer 65 in first element unit 11, and the thickness of first magnetically pinned layer 63 can be made smaller than in second magnetically pinned layer 65 in second element unit 12. However, in this structure, the film configurations including film thicknesses for first element unit 11 and second element unit 12 are different, and as a result, the manufacturing process is more complicated and leakage magnetic fields are more difficult to suppress. By using the third and fourth example embodiments that use antiferromagnetic layer 67, all magnetic field sensing elements 2 can have the same film configuration, including film thickness, even when the elements are bridged.

According to the present disclosure, a magnetic sensor can be provided in which the magnetization direction of the magnetically pinned layer is pinned in the stacking direction of the magnetically free layer, the nonmagnetic layer, and the magnetically pinned layer, and the magnetization direction of the magnetically pinned layer tends not to incline from the stacking direction.

Although preferred example embodiments of the present disclosure have been shown and described in detail, it is to be understood that various changes and modifications are possible without departing from the intent or scope of the appended claims.

### REFERENCE NUMERALS

1 magnetic sensor

2 magnetic field detection element

3 first soft magnetic layer

4 second soft magnetic layer

5 upper electrode layer

6 laminated body

7 lower electrode layer

11–14 first to fourth element units

61 magnetically free layer

62 first nonmagnetic layer

63 first magnetically pinned layer

64 intermediate layer

65 second magnetically pinned layer

66 second nonmagnetic layer

67 antiferromagnetic layer

1. A magnetic sensor comprising at least one magnetic field sensing element and at least one first soft magnetic layer, wherein
the at least one magnetic field sensing element comprises a first magnetically pinned layer, a magnetically free layer whose magnetization direction changes with respect to an external magnetic field, and a first nonmagnetic layer,
the first magnetically pinned layer, the magnetically free layer, and the first nonmagnetic layer are arranged in the order of the magnetically free layer, the first nonmagnetic layer, and the first magnetically pinned layer in a first direction,
a magnetization direction of the first magnetically pinned layer is pinned in the first direction, and
the at least one first soft magnetic layer confronts the at least one magnetic field sensing element in the first direction.

2. The magnetic sensor according to claim 1 comprising at least one second soft magnetic layer that confronts the at least one magnetic field sensing element in the first direction, wherein
the at least one magnetic field sensing element is between the at least one first soft magnetic layer and the at least one second soft magnetic layer.

3. The magnetic sensor according to claim 2 wherein
the magnetically free layer has a long axis,
at least one of the first soft magnetic layer and the second soft magnetic layer has a long axis, and
the long axis of the magnetically free layer is parallel to the long axis of at least one of the first soft magnetic layer and the second soft magnetic layer.

4. The magnetic sensor according to claim 1, wherein the first nonmagnetic layer comprises an insulating layer.

5. The magnetic sensor according to claim 1, wherein
the at least one magnetic field sensing element comprises a second magnetically pinned layer and an intermediate layer made of a nonmagnetic metal,
the first magnetically pinned layer, the magnetically free layer, the first nonmagnetic layer, the second magnetically pinned layer and the intermediate layer are arranged in the order of the magnetically free layer, the first nonmagnetic layer, the first magnetically pinned layer, the intermediate layer, and the second magnetically pinned layer in the first direction, and
a magnetization direction of the second magnetically pinned layer is pinned in the direction opposite to the magnetization direction of the first magnetically pinned layer.

6. The magnetic sensor according to claim 1, wherein
the at least one magnetic field sensing element comprises a second magnetically pinned layer and a second nonmagnetic layer,
the first magnetically pinned layer, the magnetically free layer, the first nonmagnetic layer, the second magnetically pinned layer, and the second nonmagnetic layer are arranged in the order of the second magnetically pinned layer, the second nonmagnetic layer, the magnetically free layer, the first nonmagnetic layer, and the first magnetically pinned layer in the first direction, and
a magnetization direction of the second magnetically pinned layer is pinned in the direction opposite to the magnetization direction of the first magnetically pinned layer.

7. The magnetic sensor according to claim 1, wherein
the at least one magnetic field sensing element comprises an antiferromagnetic layer,
the first magnetically pinned layer, the magnetically free layer, the first nonmagnetic layer, and the antiferromagnetic layer are arranged in the order of the magnetically free layer, the first nonmagnetic layer, the first magnetically pinned layer, and the antiferromagnetic layer in the first direction, and
the magnetization direction of the first magnetically pinned layer is pinned by exchange coupling with the antiferromagnetic layer.

8. The magnetic sensor according to claim 1, wherein
the at least one magnetic field sensing element comprises an intermediate layer made of a nonmagnetic metal, a second magnetically pinned layer, and an antiferromagnetic layer,
the first magnetically pinned layer, the magnetically free layer, the first nonmagnetic layer, the intermediate layer, the second magnetically pinned layer, and the antiferromagnetic layer are arranged in the order of the magnetically free layer, the first nonmagnetic layer, the first magnetically pinned layer, the intermediate layer, the second magnetically pinned layer, and the antiferromagnetic layer in the first direction, and
a magnetization direction of the second magnetically pinned layer is pinned in a direction opposite to the magnetization direction of the first magnetically pinned layer by exchange coupling with the antiferromagnetic layer.

9. The magnetic sensor according to claim 1, wherein a magnetization direction of the magnetically free layer is oriented orthogonally to the first direction in the absence of an external magnetic field.

10. The magnetic sensor according to claim 1, wherein a magnetization direction of the magnetically free layer has a vortex shape in a plane perpendicular to the first direction in the absence of an external magnetic field.

11. The magnetic sensor according to claim 10, wherein
the at least one magnetic field sensing element is a plurality of magnetic field sensing elements,
a magnetization direction of the magnetically free layer of each magnetic field sensing element has a vortex shape in a plane perpendicular to the first direction in the absence of an external magnetic field,
the plurality of magnetic field sensing elements is connected in series and confronts one the first soft magnetic layer in the first direction, and
a portion of the plurality of magnetic field sensing elements and the remaining portion of the plurality of magnetic field sensing elements are on both sides of a plane containing a centerline of the first soft magnetic layer that is parallel to the first direction, and magnetization directions at the centers of the vortex shapes are opposite to each other.

12. The magnetic sensor according to claim 1, wherein
said at least one magnetic field sensing element is a plurality of magnetic field sensing elements,
the magnetic sensor comprises first and second element units each having a portion of the plurality of magnetic field sensing elements,
the first and second element units are connected in series to form a group, one end of the group is connected to a power supply and the other end is grounded,
an output section is located between the first element unit and the second element unit, and
magnetization directions of the first magnetically pinned layers of the first element unit and magnetization directions of the first magnetically pinned layers of the second element unit are opposite to each other.

13. The magnetic sensor according to claim 1, wherein
the at least one magnetic field sensing element is a plurality of magnetic field sensing elements,
the magnetic sensor has first to fourth element units each having a portion of the plurality of magnetic field sensing elements,
the first and second element units are connected in series to form a first group, the third and fourth element units are connected in series to form a second group, one end of the first group and the second group is connected to a power supply, and the other ends are grounded,
the first element unit and the fourth element unit are located on the power-supply side,
the second element unit and the third element unit are located on the ground side,
the magnetic sensor includes a differentiator for determining a difference between output between the first element unit and the second element unit and output between the third element unit and the fourth element unit,
magnetization directions of the first magnetically pinned layers of the first element unit and the first magnetically pinned layers of the third element unit are the same direction, and
magnetization directions of the first magnetically pinned layers of the second and fourth element units are opposite to magnetization directions of the first magnetically pinned layers of the first and third element units.

14. The magnetic sensor according to claim 13, wherein
the at least one first soft magnetic layer is a single first soft magnetic layer, and
the single first soft magnetic layer confronts the first to fourth element units.

15. A method of manufacturing a magnetic sensor comprising steps of:
forming a group of a first element unit and a second element unit in which the first element unit and the second element unit are connected in series; and
forming at least one magnetic field sensing element in each of the first and second element units by connecting one end of the group to a power supply, grounding the other end, and providing an output section between the first and second element units, wherein:
the step of making at least one magnetic field sensing element in each of the first and second element units comprises:
arranging a first magnetically pinned layer, a magnetically free layer whose magnetization direction changes with respect to an external magnetic field, a first nonmagnetic layer, and an antiferromagnetic layer in the order of the magnetically free layer, the first nonmagnetic layer, the first magnetically pinned layer, and the antiferromagnetic layer in a first direction;
applying a magnetic field in the first direction to the first element unit while locally heating the first element unit to magnetize the first magnetically pinned layers of the first element unit; and
applying a magnetic field in a second direction opposite to the first direction to the second element unit while locally heating the second element unit to magnetize the first magnetically pinned layers of the second element unit.

16. The method of manufacturing a magnetic sensor according to claim 15, wherein the first element unit and the second element unit are locally heated by irradiating a laser beam.

17. A method of manufacturing a magnetic sensor comprising steps of:
forming first to fourth element units such that a first group is provided in which a first element unit and a second element unit are connected in series, a second group is provided in which a third element unit and a fourth element unit are connected in series, one end of the first group and one end of the second group are connected to a power supply, the other ends are grounded, the first element unit and the fourth element unit are on the power-supply side, the second element unit and the third element unit are on the grounded side, and at least one magnetic field detecting element is provided in each of the first to fourth element units; and
providing a differentiator for determining a difference between output between the first element unit and the second element unit and output between the third element unit and the fourth element unit, wherein:
the step of providing at least one magnetic field detecting element of the first to fourth element units comprises:
arranging a first magnetically pinned layer, a magnetically free layer whose magnetization direction changes with respect to an external magnetic field, a first nonmagnetic layer, and an antiferromagnetic layer in the order of the magnetically free layer, the first nonmagnetic layer, the first magnetically pinned layer, and the antiferromagnetic layer in a first direction;
applying a magnetic field to the first and third element units in the first direction while locally heating the first and third element units to magnetize the first magnetically pinned layers of the first and third element units; and
applying a magnetic field to the second and fourth element units in a second direction opposite to the first direction while locally heating the second and fourth element units to magnetize the first magnetically pinned layers of the second and fourth element units.

18. The method of manufacturing a magnetic sensor according to claim 17, wherein the first to fourth element units are locally heated by irradiating a laser beam.
